(19) United States
(12) Patent Application Publication
(10) Pub. No.: US 2026/0304826 A1
(43) Pub. Date: Oct. 1, 2026

(54) LATERAL MOSFET HAVING A VERTICAL CHANNEL

(71) Applicant: Microchip Technology Incorporated, Chandler, AZ (US)

(72) Inventors: Shesh Mani Pandey, Gilbert, AZ (US); Mazhar Hoque, Gilbert, AZ (US)

(73) Assignee: Microchip Technology Incorporated, Chandler, AZ (US)

(21) Appl. No.: 19/572,268

(22) Filed: Mar. 19, 2026

Related U.S. Application Data
(60) Provisional application No. 63/778,625, filed on Mar. 27, 2025.

(51) Int. Cl. H10D 30/65; H10D 30/01; H10D 62/00; H10D 62/10; H10D 62/13; H10D 62/17; H10D 64/01; H10D 64/27

(52) U.S. Cl. CPC H10D 30/658; H10D 30/0289; H10D 62/01; H10D 62/114; H10D 62/154; H10D 62/158; H10D 62/292; H10D 62/393; H10D 64/025; H10D 64/513; H10D 64/514; H10D 64/518

(57) ABSTRACT

A field-effect transistor (FET) may include a volume of semiconductor material that presents a top end, a bottom end, a left side, and a right side. A source and a drain may be positioned at the top end of the volume of semiconductor material and be laterally spaced apart. A trench in the volume of semiconductor material may be positioned laterally between the source and drain, with the trench extending from the top end toward the bottom end of the volume of semiconductor material and presenting a lateral trench width and a vertical trench depth. A well may extend laterally along at least the lateral trench width. A first drift region may be positioned at least in part between the well and the trench.

### RELATED APPLICATION

The present U.S. non-provisional patent application is related to and claims priority benefit of an earlier-filed U.S. provisional patent application Ser. No. 63/778,625 filed Mar. 27, 2025. The entire content of the identified earlier-filed application is incorporated by reference as if fully set forth herein.

### TECHNICAL FIELD

The present disclosure relates to vertical channel, lateral power semiconductor devices and methods of making them. More particularly, various examples of the present disclosure relate to a lateral metal oxide semiconductor field-effect transistor (MOSFET) and methods for making the same.

### BACKGROUND

A MOSFET is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, choppers, and more. It is generally desirable to improve the performance and to reduce the cost of MOSFETs, but it can be difficult to do so.

This background discussion is intended to provide information related to the present disclosure, which is not necessarily prior art.

### SUMMARY

According to examples of the present disclosure, a field-effect transistor (FET), such as a MOSFET, includes a volume of semiconductor material including a top end, a bottom end spaced vertically from the top end, a left side, and a right side spaced laterally from the left side. The FET includes a source and a drain positioned at the top end of the volume of semiconductor material. The source and the drain are laterally spaced apart. A trench is provided in the volume of semiconductor material laterally between the source and drain. The trench extends from the top end of the volume of semiconductor material toward the bottom end and presenting a lateral trench width and a vertical trench depth. A well extends laterally along at least the lateral trench width, and a first drift region is positioned at least in part between the well and the trench.

Examples of the present disclosure also provide a method of forming FET, such as a MOSFET, from a volume of semiconductor material that includes a top end, a bottom end spaced vertically from the top end, a left side, and a right side spaced laterally from the left side. A source is provided at the top end of the volume of semiconductor material. A drain is also provided at the top end of the volume of semiconductor material at a location spaced laterally from the source. A trench is formed in the volume of semiconductor material laterally between the source and the drain. A well is provided below the trench so that a first drift region is positioned at least in part between the well and trench. The operation of providing the well includes extending the well along at least a lateral width of the trench.

This summary is not intended to identify essential features of the examples, and is not intended to be used to limit the scope of the claims. These and other aspects of the present examples are described below in greater detail.

### BRIEF DESCRIPTION OF THE DRAWINGS

Examples are described in detail below with reference to the attached drawing figures, wherein:

FIG. 1 illustrates an example lateral MOSFET having a vertical channel, in accordance with the present disclosure;

FIG. 2 illustrates an example method of forming a lateral MOSFET having a vertical channel, in accordance with the present disclosure;

FIG. 3a illustrates an intermediate operation of the method of FIG. 2, in accordance with the present disclosure;

FIG. 3b illustrates an additional intermediate operation of the method of FIG. 2, in accordance with the present disclosure;

FIG. 3c illustrates an additional intermediate operation of the method of FIG. 2, in accordance with the present disclosure;

FIG. 3d illustrates an additional intermediate operation of the method of FIG. 2, in accordance with the present disclosure;

FIG. 3e illustrates an additional intermediate operation of the method of FIG. 2, in accordance with the present disclosure; and

FIG. 3f illustrates an additional intermediate operation of the method of FIG. 2, in accordance with the present disclosure.

The figures are not intended to limit the examples to the specific details illustrated therein. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, vertical, lateral, horizontal) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

The term “signal” or “electronic signal” may be used to describe electrical energy conducted through an electrically conductive medium in which an electric voltage and/or an electric current varies, or may be constant, over time. An electronic signal may be an electromagnetic wave, voltage, and/or current, and may be encoded with or representative of information.

Examples presented herein physically and functionally integrate a vertical channel, or a channel segment(s), into a lateral power semiconductor device, such as a MOSFET. Broadly, a lateral semiconductor device is a semiconductor device in which the current flows laterally (or horizontally in the illustrated embodiment) through a channel that runs primarily parallel to the top surface of the device, as a result of the source and drain being positioned on the same end of the volume of semiconductor material. Introducing a vertical segment(s) of the channel, particularly adjacent the source, to what would otherwise be a lateral channel device provides an additional axis of control for current flow through the device. A tighter/more restrictive channel may result in charge carriers traveling from source to drain in less time, thereby enhancing overall device performance.

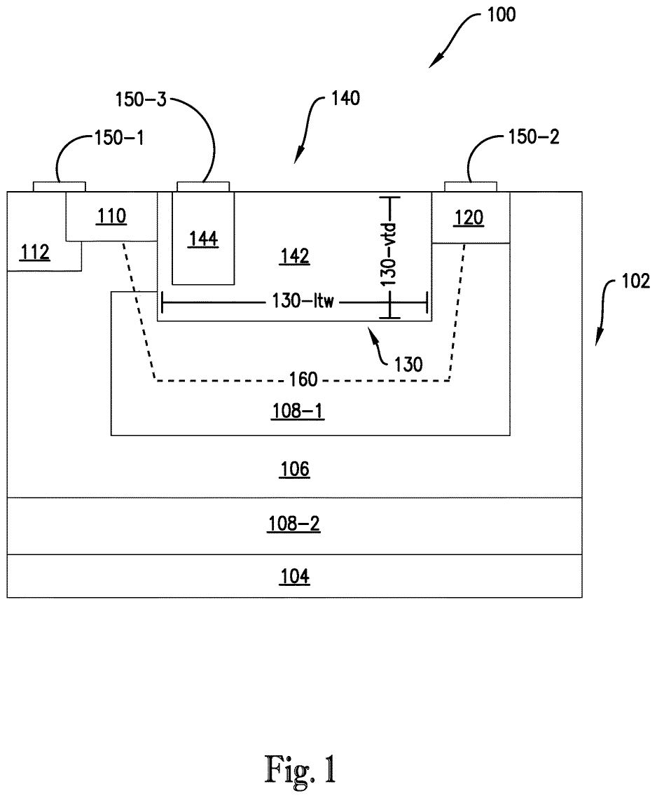

FIG. 1 illustrates a cross section of a lateral MOSFET 100 having a channel 160 that includes one or more vertical channel segments, in accordance with the present disclosure. Such a channel will be henceforth referred to as a “vertical channel.” The MOSFET 100 may comprise, or otherwise be formed at least in part from, a volume of semiconductor material 102. The volume of semiconductor material 102 includes: a top end, or top; a bottom end, or bottom, spaced vertically from the top; a left side; and a right side spaced laterally from the left side. The volume of semiconductor material 102 includes, or is formed on, a substrate 104. The substrate 104 is positioned at, or adjacent to, the bottom end of the volume of semiconductor material 102. The substrate 104 comprises, or is formed from, an N+ material. The MOSFET 100 further includes a well, or well region 106; first and second drift regions 108-1, 108-2; a source 110; a body 112; a drain 120; a trench 130; and a gate 140.

The source 110 and drain 120 are positioned, or formed, at the top end of the volume of semiconductor material 102. The source 110 and the drain 120 are laterally spaced apart from one another. The source 110 is located adjacent to the left side of the volume of semiconductor material 102, while the drain 120 is located adjacent to the right side of the volume of semiconductor material 102. A body 112 is positioned adjacent to the source 110. The source 110 and drain 120 comprise, or are formed from, an N+ material. The body 112 comprises, or is formed from, a P+ material.

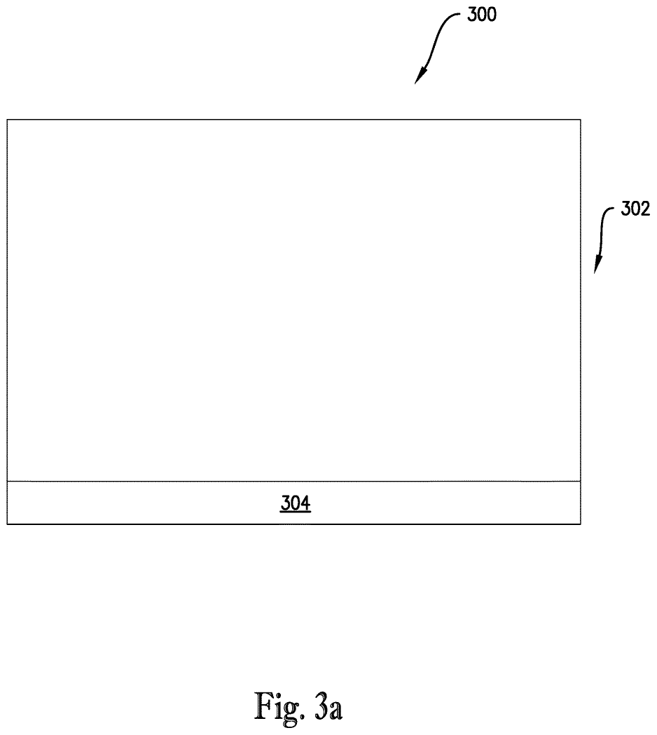

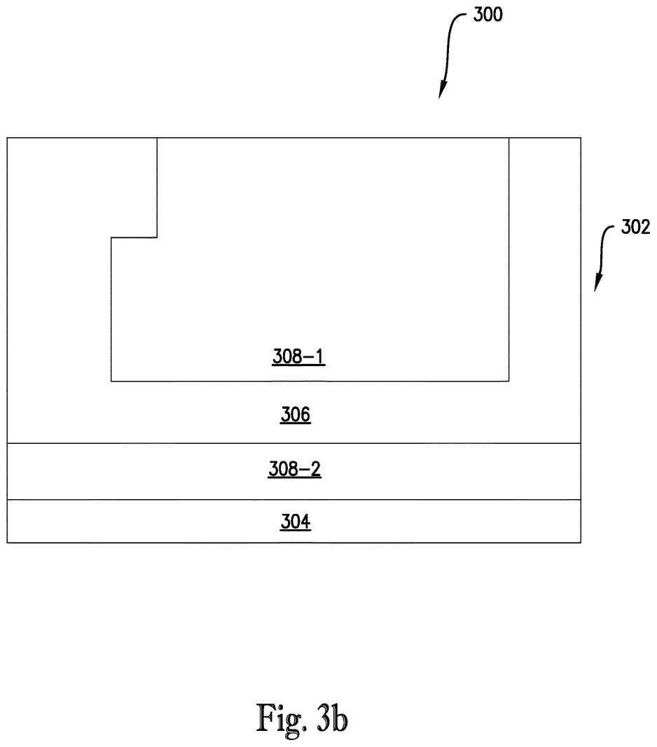

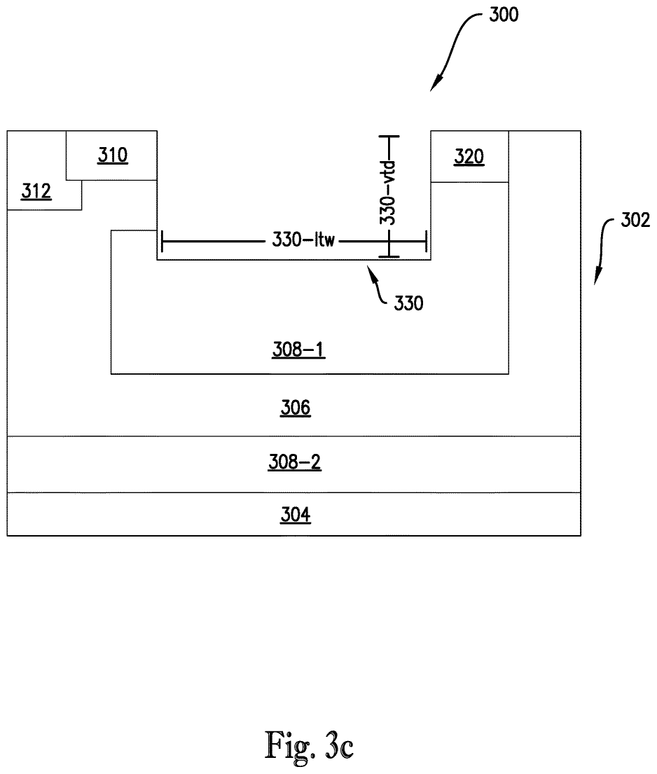

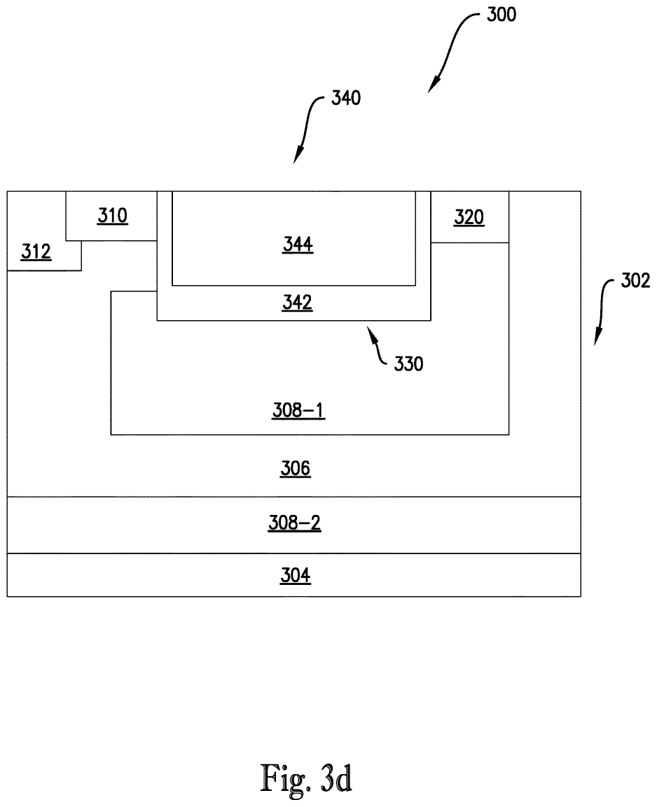

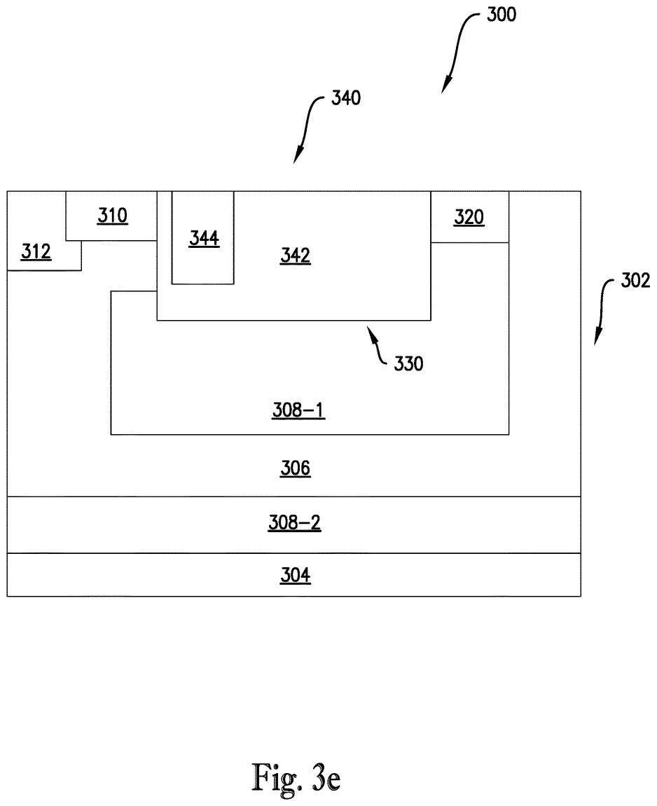

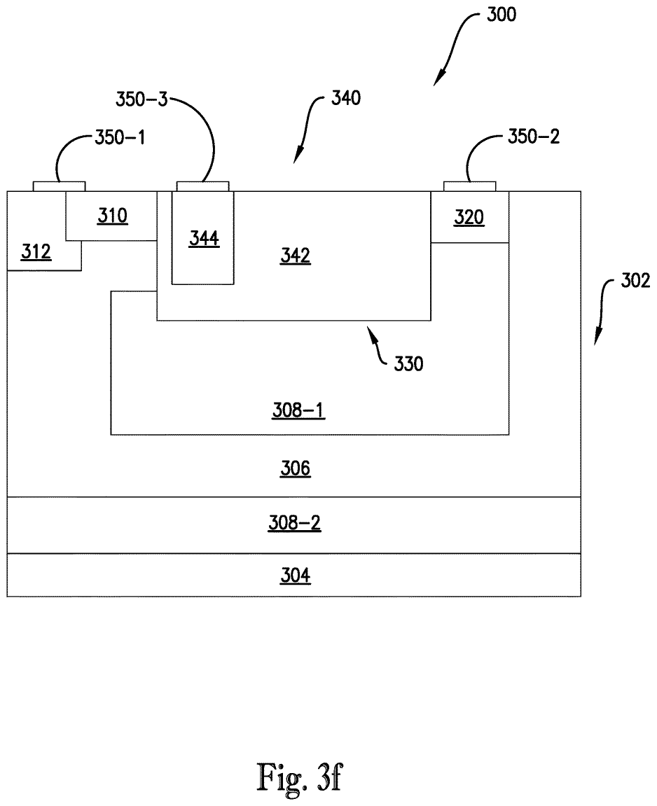

A trench 130 is positioned, or formed, within the volume of semiconductor material 102 between the source 110 and the drain 120. As illustrated, the trench 130 extends (i) from the top end toward the bottom end of the volume of semiconductor material 102, and (ii) laterally, continuously, and fully between the source 110 and the drain 120. In the illustrated example of the MOSFET 100, the trench 130 serves to contain the gate. The trench 130 presents a lateral trench width 130-ltw and a vertical trench depth 130-vtd (see also FIG. 3C). In the illustrated example, the trench width 130-ltw is continuous from the bottom of the trench 130 to the top end of the volume of semiconductor material, and the trench depth 130-vtd is continuous between the left and right margins of the trench 130, such that the trench presents a generally orthogonal (rectangular in the illustrated example) shape. However, according to certain examples, the trench width 130-ltw and/or trench depth 130-vtd may vary laterally or vertically, respectively. For example, the trench may alternatively have a first depth where the layer of polysilicon material (described below) is located and a second (e.g., shallower) depth where only dielectric material (described below) is located. As yet another example, the side of the trench alongside the drain might vary (e.g., be offset) between the bottom of the trench and the first end of the volume of semiconductor material.

The well, or well region, 106 extends laterally from the source 110, spanning the full lateral width 130-lwt of the trench 130. In various examples of the present disclosure including those in accordance with FIG. 1, the well 106 may extend beyond the drain 120, such that a portion of the well 106 is located at, or toward, the top end of the volume of semiconductor material 102 and between the drain 120 and the right side of the volume of semiconductor material 102. In the illustrated example, the well 106 extends continuously between the second drift region 108-2 and the top end of the volume of semiconductor material 102, thereby entirely isolating the first drift region 108-1 from the right side of the volume of semiconductor 102. The well 106 may also extend between the first drift region 108-1 and the left side of the volume of semiconductor material 102. As illustrated, the well 106 extends continuously between the second drift region 108-2 and the source 110 and body 112, such that these components cooperate to entirely isolate the first drift region 108-1 from the left side of the volume of semiconductor material. The well 106, as illustrated in FIG. 1, is essentially U-shaped and cooperates with the trench (and particularly the gate oxide described below) to entirely contain the first drift region 108-1.

The illustrated first drift region 108-1 is positioned within the well 106. The first drift region 108-1 includes, or comprises, three (3) portions (or sections/segments). These three portions include: (1) a first vertical portion extending from the drain toward the bottom of the volume of semiconductor material 102, (2) a lateral portion extending from the first vertical portion toward the left side of the volume of semiconductor material 102 and spanning the lateral trench width 130-ltw, and (3) a second vertical portion extending from the lateral portion toward the source. A portion of the well 106 may be positioned between the source 110 and the second vertical portion of the first drift region 108-1. However, it will be appreciated that the geometry (e.g., size and shape) of the portion of the well 106 that is positioned between the source 110 and the second vertical portion of the first drift region 108-1 may differ from what is illustrated in the drawing figures. That is to say, from a review of the drawing figures and the discussion herein, the various dimensions, relative positions, composition, and/or configuration of any of the features, regions, or sub-regions described herein may vary across the respective examples without departing from the scope of the present disclosure.

The well region 106 comprises, or is formed from, a P-type material and the first drift region 108-1 comprises, or is formed from, an N-type material.

The well region 106 is interposed between and fully separates the first and second drift regions 108-1, 108-2. Like the first drift region 108-1, the second drift region 108-2 comprises, or is formed from, an N-type material.

The gate 140, which is located, or formed, in the trench 130 includes a layer of dielectric material 142 and a layer of polysilicon material 144. The layer of polysilicon material extends laterally less than half the lateral trench width 130-lwt. Furthermore, the layer of dielectric material 144 may occupy the majority of the trench 130.

The MOSFET 100 may include electrical terminals, or contacts, 150-1, 150-2, and 150-3 to facilitate the application of various electrical signals thereto. More specifically, the first electrical terminal 150-1 may be added to the source 110. The second electrical terminal 150-2 may be applied to, or formed on, the drain 120. The third electrical terminal 150-3 may be applied to, or formed on, or over, a portion of the gate 140 (e.g., on top of the polysilicon layer 144).

In operation, when a gate-source voltage (Vgs) is applied between the source terminal 150-1 and the gate terminal 150-2, the generated electric field creates an inversion layer at the semiconductor-dielectric interface within the volume of semiconductor material 102. The inversion layer may provide a channel(s) 160 through which electrical current can flow when a drain-source voltage (Vds) is applied between the source terminal 150-1 and the drain terminal 150-2. In accordance various examples of the present disclosure, the channel 160 includes two vertical portions, or segments, and one lateral portion, or segment. The first vertical portion of the channel 160 originates at the drain 120 and passes through the first vertical portion of the first drift region 108-1 before turning, at which point the lateral channel segment passes through the lateral portion of the first drift region 108-1. From there, the channel 160 turns again, extending vertically through the second vertical portion of the first drift region 108-1 before terminating at the source 110.

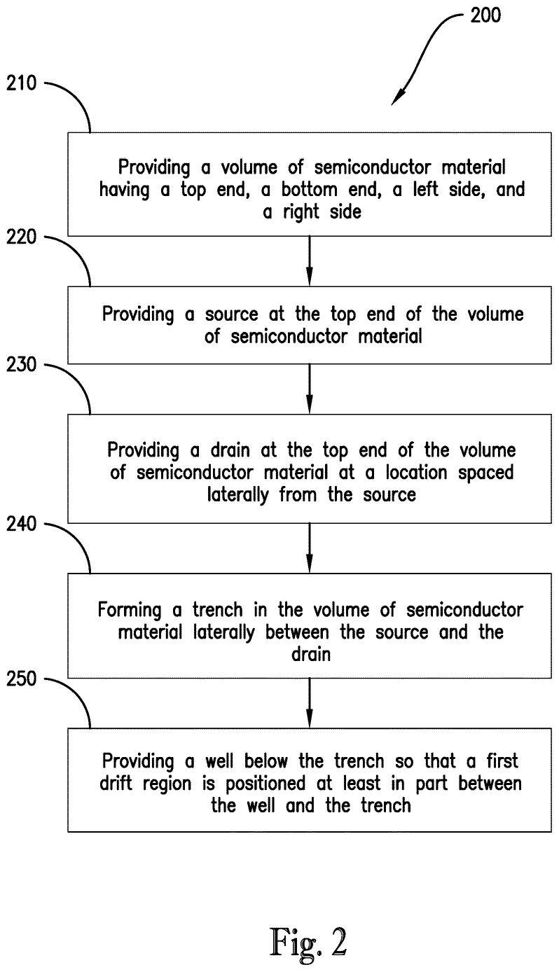

FIG. 2 illustrates a method 200 for forming a MOSFET in accordance with the present disclosure. The method 200 may be used to form MOSFET(s) from a volume of semiconductor material. According to various examples of the present disclosure, the MOSFET 100 and MOSFETs substantially similar or identical thereto may be formed from the method 200.

Broadly, any feature, portion, area, or volume (doped or undoped) of a MOSFET or any other semiconductor device formed by the method 200 may be formed via any process suitable for forming said feature(s), portion(s), area(s), or volume(s). For instance, ion implantation and other similar/suitable processes may be used to form wells, sources, bodies, and the like, without limitation. Epitaxial growth and similar/suitable processes may be used to form substrates and initial, intermediate, or precursor, volumes of semiconductor material. Etching and other similar/suitable processes may be used to remove select portions of semiconductor material once formed (e.g., to form a trench within a volume(s) of semiconductor material), or to remove portions of oxide, metal, or metal alloy layers, without limitation. Deposition and other similar/suitable processes may be used to fill trenches once etched, to form electrical terminals (or contacts), and the like, without limitation.

Performance of the method 200 may, at various stages throughout, may result in formation of an intermediate, or precursor, volume of semiconductor material, which in turn, may be formed into MOSFETs in accordance with the present disclosure.

FIGS. 3a-3f collectively illustrate cross-sections of a MOSFET 300, which may be substantially similar or identical to the MOSFET 100 of FIG. 1. Accordingly, the various features, regions, and/or sub-regions included in MOSFET 300 may be substantially similar or identical to the corresponding feature, region, and/or sub-region of MOSFET 100. For instance, source 310 may be substantially similar or identical to source 110, substrate 304 may be substantially similar or identical to substrate 104, electrical terminal 350-2 may be substantially similar or identical to electrical terminal 150-2, and so on, without limitation. Accordingly, for the sake of brevity, redundant description of features, regions, and/or sub-regions common to MOSFETs 100, 300 have been greatly reduced, if not eliminated, herein.

The cross-sections of the MOSFET 300 illustrated in FIGS. 3a-3f illustrate progress in the formation of the MOSFET 300 at various, intermediate points in time throughout the performance of the method 200. Accordingly, the intermediate cross-sections illustrated in FIGS. 3a-3f may be referenced alongside discussion of the operations of the method 200.

Referring to FIG. 2, operation 210 may include forming, or otherwise providing, a volume of semiconductor material 302 having a top end, a bottom end, a left side, and a right side. The top end is spaced vertically from the bottom end, and the left side is spaced laterally from the right side. The volume of semiconductor material may be formed on (e.g., by epitaxial growth), or include, a substrate 304. The substrate may be pre-formed. Referring to FIG. 3a, the substrate may comprise, or be formed from, an N+material, and the remaining volume of semiconductor material 302 may comprise, or be formed from, a N-type material. The volume of semiconductor material 302 may be formed on, along, or adjacent to the substrate 304.

FIG. 3b depicts implantation of P-type region within the N-type semiconductor material. It will be appreciated that the P-type region generally forms the well 306.

FIG. 3c combines operations 220, 230, and 240. Operations 220 and 230 may respectively include forming, or otherwise providing (e.g., by implantation) a source 310 and a drain 320 at the top end of volume of semiconductor material 302. The source 310 and drain 320 are formed adjacent to the left and right side of the volume of semiconductor material 302, respectively. Source 310 and drain 320 are spaced laterally from each other. A body 312 is formed (e.g., by implantation), or otherwise provided, adjacent to source 310, in the upper-left corner of the volume of semiconductor material 302. Operation 240 includes forming (e.g., via etching) a trench 330 that has a lateral trench width 330-lwt and a vertical trench depth 330-vtd. The trench 330 is positioned in the volume of semiconductor material laterally between the source 310 and drain 320. As illustrated, the trench 330 fully spans the lateral space between the source 310 and the drain 320.

At operation 250, a well 306 is formed, or otherwise provided below, or beneath, the trench 330 so that a first drift region 308-1 is positioned at least in part between the well 306 and the trench 330. Ion implantation, or any other suitable doping operation may be used to form the well 306. The operation(s) of providing the well 306 further include extending the well 306 along at least the lateral width 330-ltw of trench 330. It will be appreciated that, in various examples of the present disclosure, the doping operation(s) corresponding to the formation of well 306 may occur elsewhere in time during the performance of the method 200. For example, the doping operation(s) corresponding to the formation of the well 306 may occur after completion of operation 210 but before any of the operations 220, 230, or 240 begin, as suggested by FIG. 3b. Regardless of when exactly during the performance of the method 200 the doping operation(s) for forming the well 306 occur, the well 306 may be spaced from the substrate 304 and may fully separate the first drift region 308-1 from a second drift region 308-2. As illustrated, the second drift region 308-2 is positioned between the well region 306 and substrate 304.

The operation(s) of forming the well may also include forming, e.g., via implantation: (i) a first vertical well portion extending from the drain 320 toward the bottom end of the volume of semiconductor material 302, (ii) a lateral well portion extending from the first vertical well portion and spanning the lateral trench width 330-ltw, and (iii) a second vertical well portion extending from the lateral well portion toward the source 310. A portion of the second vertical portion of well 306 may be interposed between the second vertical portion of first drift region 308-1 and the source 310.

A channel (not illustrated in FIGS. 3a-3f) that is substantially similar or identical to the channel 160 of FIG. 1 may extend through first vertical, lateral, and second vertical channel portions when electrical signals are applied to electrical contacts, or terminals, 350-1, 350-2, and/or 350-3. Additional details on formation of electrical contacts 350-1, 350-2, and 350-3, as well as how to apply electrical signals thereto to form a channel, can be found above in the description of FIG. 1.

Additional details for each of the operations in the method 200 and/or corresponding to the intermediate steps of forming the MOSFET 100 can be found in connection with the descriptions of FIG. 1.

### FEATURE COMBINATIONS

According to various examples of the present disclosure, a field-effect transistor (FET), such as a MOSFET, may include a volume of semiconductor, a source, a drain, a trench, a well, and a first drift region. The volume of semiconductor material may include a top end, a bottom end spaced vertically from the top end, a left side, and a right side spaced laterally from the left side. The source may be positioned at the top end of the volume of semiconductor material. The drain may be positioned at the top end of the volume of semiconductor material, with the source and drain being laterally spaced apart. The trench may be in the volume of semiconductor material laterally between the source and the drain. The trench may extend from the top of the volume of semiconductor material toward the bottom end and present a lateral trench width and a vertical trench depth. The well may extend laterally along at least the lateral trench width. The first drift region may be at least in part between the well and the trench.

In various other examples, a method of forming a FET is disclosed. The method may include the operation of providing a volume of semiconductor material that includes a top end, a bottom end spaced vertically from the top end, a left side, and a right side spaced laterally from the left side. A source may be provided at the top end of the volume of semiconductor material, and a drain may be provided at the top end of the volume of semiconductor material at a location spaced laterally from the source. A trench may be formed in the volume of semiconductor material laterally between the source and the drain. A well may be provided below the trench so that a first drift region is positioned at least in part between the well and the trench. The operation of providing the well may include extending the well along at least a lateral width of the trench.

In combination with any of the previous examples, the first drift region may be positioned within the well.

In combination with any of the previous examples, the source may be located adjacent the left side of the volume of semiconductor material, the drain may be located adjacent the right side of the volume of semiconductor material, and the well may extend from the source, laterally the full width of the trench, and beyond the drain, such that a portion of the well is located at the top of the volume of semiconductor material between the drain and the right side of the volume of semiconductor material.

In combination with any of the previous examples, the well may be positioned between the first drift region and the left side of the volume of semiconductor material.

In combination with any of the previous examples, a second drift region may be positioned beneath the well so as to be fully separated from the first drift region.

In combination with any of the previous examples, a gate may be located in the trench.

In combination with any of the previous examples, a gate may include a layer of dielectric material and a layer of polysilicon material.

In combination with any of the previous examples, a layer of polysilicon material may extend laterally less than half the lateral trench width.

In combination with any of the previous examples, a layer of dielectric material may occupy the majority of the trench.

In combination with any of the previous examples, the trench may extend continuously between source and drain.

In combination with any of the previous examples, the first drift region may include a first vertical portion extending from the drain toward the bottom of the volume of semiconductor material, a lateral portion extending from the first vertical portion and spanning the lateral trench width, and a second vertical portion extending from the lateral portion toward the source.

In combination with any of the previous examples, a portion of the well may be positioned between the source and the second vertical portion of the first drift region.

In combination with any of the previous examples, a channel may extend through the first drift region between the source and the drain.

In combination with any of the previous examples, a substrate may be positioned at the bottom end of the volume of semiconductor material, and a second drift region may be positioned between the well and the substrate, with the well fully separating the second drift region from the first drift region.

In combination with any of the previous examples, a body may be positioned adjacent to the source. Each of the source, the drain, and a substrate may comprise an N+material. Each of the first and second drift regions may comprise an N-type material. The well may comprise a P-type material. The body may comprise a P+material.

In combination with any of the previous examples, the operation of providing the volume of semiconductor material may include growing the volume of semiconductor material on a substrate such that the bottom end is adjacent the substrate. The operation of providing the well may include spacing the well from the substrate so that a second drift region is positioned between the well and the substrate with the well fully separating the second drift region from the first drift region.

In combination with any of the previous examples, a gate may be formed within the trench.

In combination with any of the previous examples, the operation of forming the gate may include providing a layer of dielectric material and a layer of polysilicon material within the trench. The operation of providing the layer of dielectric material may include occupying the majority of the trench with the dielectric material.

In combination with any of the previous examples, the operation of providing the well may include implanting a first vertical well portion to extend from the drain toward the bottom end of the volume of semiconductor material, implanting a lateral well portion to extend from the first vertical well portion and span a lateral trench width, and implanting a second vertical well portion to extend from the lateral portion toward the source.

### GENERAL CONSIDERATIONS

In this description, references to “one embodiment,” “an embodiment,” “embodiments,” “an example,” “one example,” or “examples” mean that the feature or features being referred to are included in at least one embodiment or example of the technology. Separate references to “one embodiment,” “an embodiment,” “embodiments,” “an example,” “one example,” or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

Although described herein with regard or in relation to one or more particular kinds of electronic devices (e.g., junction field-effect transistor, metal oxide semiconductor field-effect transistor), the technology may be more broadly applicable to one or more other kinds of electronic devices as well.

One with ordinary skill in the art will recognize that the technology described herein may, when applicable, be implemented in enhancement mode or depletion mode.

Further, the technology described herein may, when applicable, be implemented as an N-channel or P-channel device, wherein, in general, regions that are N-doped or P-doped in N-channel implementations may be, respectively, P-doped or N-doped in P-channel implementations.

Additionally, the various example materials identified herein may, in some aspects, be replaced and/or supplemented with substantially any other suitable material. For example, gate material may include polysilicon, a metal or alloy of metals, or other suitable material; gate oxide or dielectric may include silicon dioxide (SiO₂), aluminum oxide (Al₂O₃), hafnium dioxide (HfO₂), silicon nitride (Si₃N₄), or other suitable material; and semiconductor material may include silicon carbide (SiC), gallium nitride (GaN), zinc oxide (ZnO), or other suitable material.

Additionally, in general, unless otherwise specified or unless one with ordinary skill in the art would understand otherwise, doping characterized as “+” (e.g., P++) will have a relatively higher concentration of dopants than “+” (e.g., P+) doping, “+” doping will have a relatively higher concentration than “-well” (e.g., P-well) doping, and “-well” doping will have a relatively higher concentration of doping than “−” (e.g., P−) doping. In general, doping concentrations (typically measured in parts-per-cubic-centimeter) for contact implants (e.g., sources, drains, body contacts) may be approximately between 5×10\hat{ }18 and 1×10\hat{ }22; doping concentrations for channel and threshold forming implants (e.g., P-wells) may be approximately between 5×10\hat{ }15 and 5×10\hat{ }17; doping concentrations for shielding implants may be approximately between 5×10\hat{ }17 and 5×10\hat{ }19; and doping concentrations for conductivity improvement implants (e.g., N-doping in the junction field-effect transistor neck region of a metal oxide semiconductor field-effect transistor) may be approximately between 1×10\hat{ }17 and 1×10\hat{ }19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

Additionally, although only one or a few instances of a device or apparatus may be described herein, it will be appreciated that some applications may involve many such devices or apparatuses, which may be different from, substantially similar to, or identical to the described device or apparatus, and which may be arranged (e.g., in an array) on a larger extension of the volume of semiconductor material. In that light, references to a right and/or left side of a volume of semiconductor material may be to the conceptual limit of a particular unit cell and not to an actual physical end of the material.

What is claimed is:

1. A field-effect transistor (FET) comprising:
a volume of semiconductor material including a top end, a bottom end spaced vertically from the top end, a left side, and a right side spaced laterally from the left side;
a source positioned at the top end of the volume of semiconductor material;
a drain positioned at the top end of the volume of semiconductor material, with the source and drain being laterally spaced apart;
a trench in the volume of semiconductor material laterally between the source and the drain, the trench extending from the top end of the volume of semiconductor material toward the bottom end and presenting a lateral trench width and a vertical trench depth;
a well extending laterally along at least the lateral trench width; and
a first drift region positioned at least in part between the well and the trench.

2. The FET of claim 1, the first drift region being positioned within the well.

3. The FET of claim 2,
the source being located adjacent the left side of the volume of semiconductor material,
the drain being located adjacent the right side of the volume of semiconductor material,
the well extending from the source, laterally the full width of the trench, and beyond the drain, such that a portion of the well is located at the top end of the volume of semiconductor material between the drain and the right side of the volume of semiconductor material.

4. The FET of claim 3,
the well being positioned between the first drift region and the left side of the volume of semiconductor material.

5. The FET of claim 1, comprising:
a second drift region positioned beneath the well so as to be fully separated from the first drift region.

6. The FET of claim 1, comprising:
a gate located in the trench.

7. The FET of claim 6,
the gate including a layer of dielectric material and a layer of polysilicon material.

8. The FET of claim 7,
the layer of polysilicon material extending laterally less than half the lateral trench width.

9. The FET of claim 7,
the layer of dielectric material occupying the majority of the trench.

10. The FET of claim 1,
the trench extending continuously between source and drain.

11. The FET of claim 1,
the first drift region including—
a first vertical portion extending from the drain toward the bottom end of the volume of semiconductor material,
a lateral portion extending from the first vertical portion and spanning the lateral trench width, and
a second vertical portion extending from the lateral portion toward the source.

12. The FET of claim 11,
a portion of the well being positioned between the source and the second vertical portion of the first drift region.

13. The FET of claim 11, comprising:
a channel extends through the first drift region between the source and the drain.

14. The FET of claim 1, comprising:
a substrate positioned at the bottom end of the volume of semiconductor material; and
a second drift region positioned between the well and the substrate,
the well fully separating the second drift region from the first drift region.

15. The FET of claim 14, comprising:
a body positioned adjacent the source,
each of the source, the drain, and the substrate comprise an N+ material,
each of the first and second drift regions comprise an N-type material,
the well comprises a P-type material,
the body comprises a P+ material.

16. A method of making a field-effect transistor (FET) comprising:
providing a volume of semiconductor material that includes a top end, a bottom end spaced vertically from the top end, a left side, and a right side spaced laterally from the left side;
providing a source at the top end of the volume of semiconductor material;
providing a drain at the top end of the volume of semiconductor material at a location spaced laterally from the source;
forming a trench in the volume of semiconductor material laterally between the source and the drain; and
providing a well below the trench so that a first drift region is positioned at least in part between the well and trench,
the operation of providing the well including extending the well along at least a lateral width of the trench.

17. The method of claim 16,
the operation of providing the volume of semiconductor material including growing the volume of semiconductor material on a substrate such that the bottom end is adjacent the substrate,
the operation of providing the well including spacing the well from the substrate so that a second drift region is positioned between the well and the substrate, with the well fully separating the second drift region from the first drift region.

18. The method of claim 16, comprising:
forming a gate within the trench.

19. The method of claim 18,
the operation of forming the gate including providing a layer of dielectric material and a layer of polysilicon material within the trench,
the operation of providing the layer of dielectric material including occupying the majority of the trench with the dielectric material.

20. The method of claim 16,
the operation of providing the well including implanting a first vertical well portion to extend from the drain toward the bottom end of the volume of semiconductor material, implanting a lateral well portion to extend from the first vertical well portion and span a lateral trench width, and implanting a second vertical well portion to extend from the lateral portion toward the source.
